(19) United States
(12) Patent Application Publication
(10) Pub. No.: US 2002/0086489 A1
(43) Pub. Date: Jul. 4, 2002

(54) Use of sidewall spacer in PNP layout to minimize silicided area of emitter

(76) Inventor: Amitava Chatterjee, Plano, TX (US)

Correspondence Address: TEXAS INSTRUMENTS INCORPORATED, P O BOX 655474, M/S 3999, DALLAS, TX, 75265

(21) Appl. No.: 10/010,477

(22) Filed: Nov. 8, 2001

Related U.S. Application Data
(60) Provisional application No. 60/259,279, filed on Dec. 31, 2000.

(51) Int. Cl. H01L 21/331; H01L 27/082

(52) U.S. Cl. 438/338; 257/584

(57) ABSTRACT

Silicide formation on the surface of the emitter in a vertical BJT is blocked by adding polysilicon lines with nitride sidewalls. The poly and nitride prevent silicide formation where they are deposited, decreasing the ratio of silicided area to total area and increasing emitter efficiency.

### BACKGROUND AND SUMMARY OF THE INVENTION

The present invention relates to integrated circuit structures and fabrication methods, and particularly to formation of bipolar devices.

Modern CMOS integrated circuit processes are normally optimized for features such as power consumption, performance of the NMOS and PMOS transistors, and cost, but NOT for fabrication of bipolar transistors. (Processes which are optimized for both MOS and bipolar transistor qualities are referred to as “BiCMOS” processes.) However, it has long been recognized that even a low-gain bipolar transistor can be very useful for some purposes, such as bandgap voltage references. Almost any bulk CMOS process permits a crude PNP transistor to be provided without process modifications, and many bulk CMOS processes provide a “free” NPN as well. However, the performance of such “free” bipolars is usually very low.

One of the performance parameters of a bipolar transistor is current gain. The emitter efficiency in a bipolar, which determines the gain of the device, depends heavily on the ratio of emitter doping to base doping near the emitter-base junction. Transistors in bipolar or BiCMOS processes may have current gains in the neighborhood of 100, whereas the “free” bipolars in a CMOS process often have gain values of less than ten. While the availability of any bipolar is useful for some purposes, it would be even more useful to provide bipolars with higher gain, if this could be done without drastic process modification.

The present application discloses an improvement to bipolar transistors, especially (but not only) those formed in CMOS processes.

The present inventors have realized that silicide cladding on the emitter surface has two undesirable effects: first, silicide formation tends to deplete dopant atoms from the emitter diffusion, which undesirably reduces the emitter efficiency. Second, the “recombination velocity” in the silicide is almost infinite, so that the silicide acts as a sink for minority carriers. With a shallow emitter diffusion, this implies that the population of minority carriers near the silicide-silicon interface will be reduced to equilibrium levels, which also reduces the gain of the bipolar.

The present application teaches that the silicided area of the bipolar transistor's emitter should be reduced, e.g. by sidewall spacers which narrow the emitter area exposed for silicide formation after the emitter dopants have been implanted. This reduces the ratio of emitter contact area to emitter junction area, and ameliorates both of the problems noted in the preceding paragraph. This is particularly advantageous in CMOS processes which are not optimized for bipolar performance, since the junction depth and silicide cladding steps in such processes may be driven by other constraints.

In the preferred embodiment, silicide formation on the surface of an emitter is partially blocked by first depositing polysilicon lines with nitride sidewalls. The polysilicon lines are placed at minimum spacing for the technology, minimizing the area for silicide formation. The sidewalls formed on the poly lines further cover the emitter surface area, leaving less area for silicide formation. In the preferred embodiment, the silicide is formed on about a third of the emitter surface. Since silicide formation reduces emitter efficiency, the innovative layout increases emitter efficiency.

Advantages of the disclosed methods and structures, in various embodiments, can include one or more of the following:

ability to produce higher gain BJTs in CMOS process with no process alteration;

increased emitter efficiency without added process cost.

### BRIEF DESCRIPTION OF THE DRAWINGS

The disclosed inventions will be described with reference to the accompanying drawings, which show important sample embodiments of the invention and which are incorporated in the specification hereof by reference, wherein:

FIG. 1 shows a cross section of a partially fabricated integrated circuit structure.

FIG. 2 shows a cross section of a partially fabricated integrated circuit structure according to a preferred embodiment.

FIG. 3 shows a detail of a partially integrated circuit structure according to a preferred embodiment.

FIG. 4 shows a top view of a preferred embodiment.

FIG. 5 shows a flow chart with key steps in the preferred embodiment.

### DETAILED DESCRIPTION OF THE PREFERRED EMBODIMENTS

The numerous innovative teachings of the present application will be described with particular reference to the presently preferred embodiment. However, it should be understood that this class of embodiments provides only a few examples of the many advantageous uses of the innovative teachings herein. In general, statements made in the specification of the present application do not necessarily delimit any of the various claimed inventions. Moreover, some statements may apply to some inventive features but not to others.

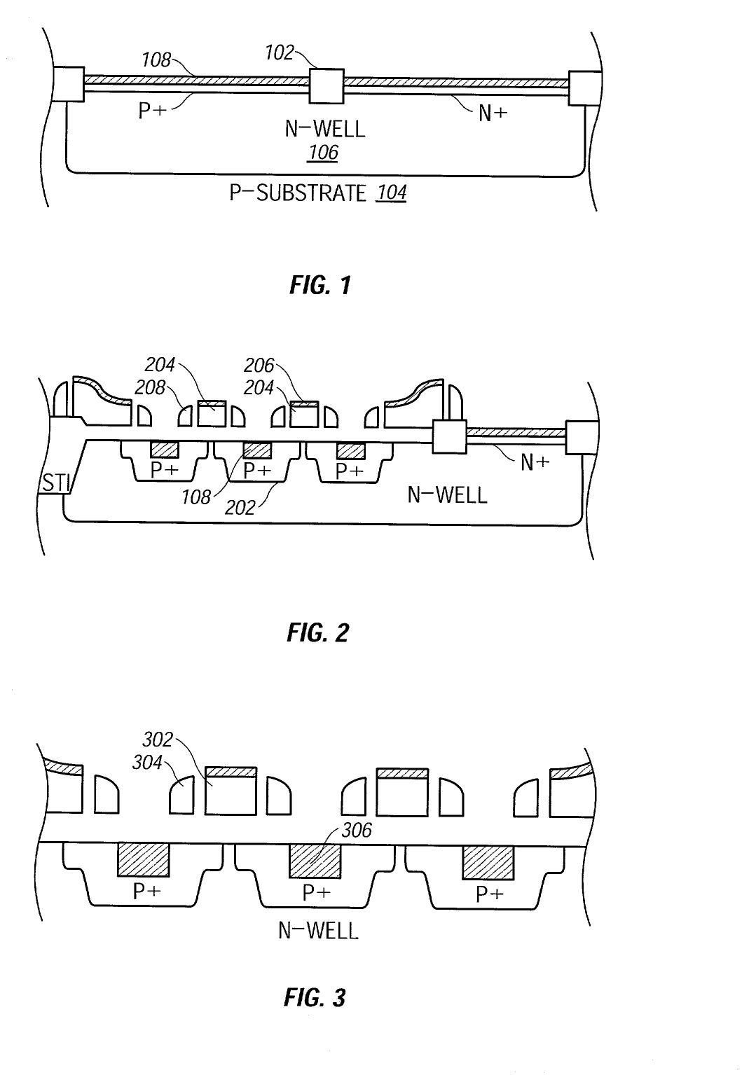

FIG. 1 shows a conventional vertical pnp transistor. Shallow trench isolation 102 (STI) separates the devices, which are formed on a p substrate 104 with an n well 106. A p+ layer has a silicide 108 formed on its top surface. Note that the silicide extends into the depth of the p+ layer. The silicide has a tendency to consume nearby dopant ions, and because of a nearly infinite recombination velocity in the silicide, this reduces the bipolar gain by reducing the emitter dopants. Therefore the larger the area of the silicide on the p+ layer, the more dopants are consumed, decreasing the emitter dopant concentration of the pnp transistor. This decreases emitter efficiency.

FIG. 2 shows a vertical pnp transistor according to a preferred embodiment. The top of the active layer (where the emitter 202 is located) has polysilicon lines 204 with silicide caps 206 deposited on it. These lines have sidewalls 208 formed on them increasing their width. The poly lines are placed at minimum spacing (about 0.2 microns apart) and are of minimum width (about 0.15 microns) for lithographic and etch processes (or whatever process is used to pattern poly). The poly lines and sidewalls block the silicide from forming where they cover the emitter surface. In the preferred embodiment, a combination of nitride sidewalls are used, which block the cobalt based (CoSi₂) silicide.

In the preferred embodiment, the ratio of the silicided area to the total area of the emitter is minimized to the extent the technology allows. No added processing is required to accomplish this. Only layout manipulation is necessary. Thus the innovative layout is especially useful in standard CMOS processes where process cost for creating BJTs is avoided or minimized. The invention is advantageous in any context as a way to improve the free bipolar in a process which is not optimized for bipolar performance, including BiCMOS processes as well.

FIG. 3 shows a more detailed view of the surface of the emitter during fabrication. In this view, the emitter has poly lines 302 with sidewalls 304 formed on its surface where the silicide 306 is later formed. Since the silicide 306 is blocked by the poly 302 and sidewalls 304, the silicide only forms between the sidewalls on the surface, thus reducing the total silicided area and the ratio of silicided to unsilicided emitter surface area. After addition of the poly and sidewalls, the proportional area of the emitter that is finally silicided is reduced to nearly a third of the emitter's area.

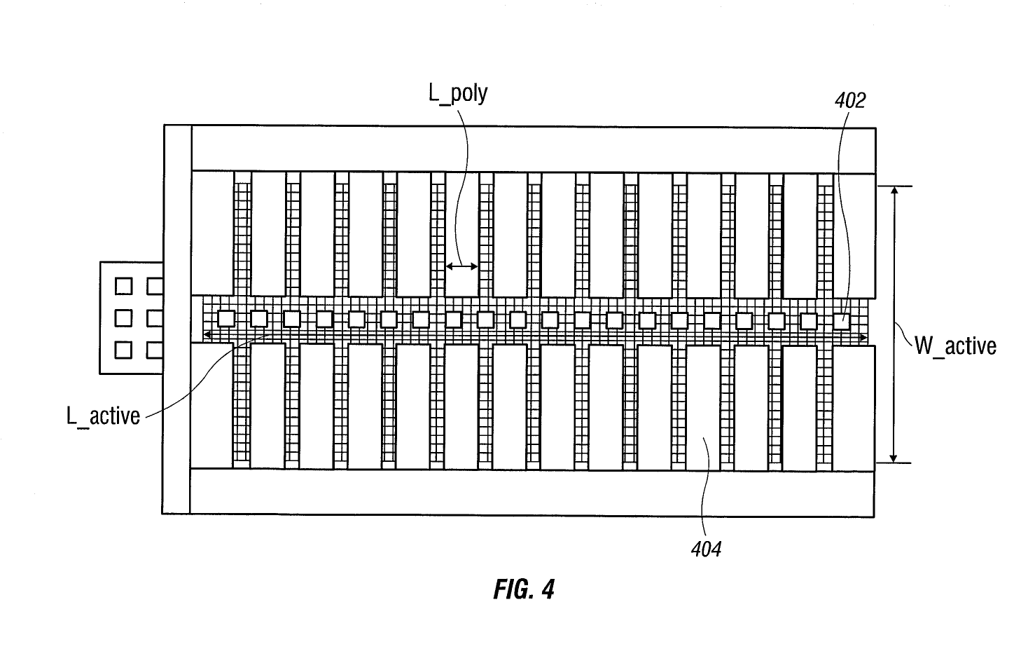

However, some surface area of the emitter must be used for forming contacts. FIG. 4 shows a preferred embodiment of the innovations including contacts 402 and the necessary poly 404 configuration. The active area is covered with the poly lines 404 and sidewalls (shown as a single structure in this figure for simplicity). The poly lines are broken in a strip down the center to make room for the contacts 402 to the emitter. The exact location of the contacts will of course depend on other process constraints, and need not be exactly as depicted in the preferred embodiment. Since the poly lines are placed at minimum spacing, there would otherwise be no room for these contacts. By breaking the poly lines at the center (rather than at an end) the resistance to the current flowing between the adjacent poly lines is reduced.

At the sides of the emitter area, shallow trench isolation isolates the device from nearby devices.

Though the preferred embodiment shows straight poly lines, the configuration of the poly is limited only by the process technology. Typical processes allow for 45 degree angled lines, for instance, and shapes or patterns of many kinds are within the contemplation of the present application.

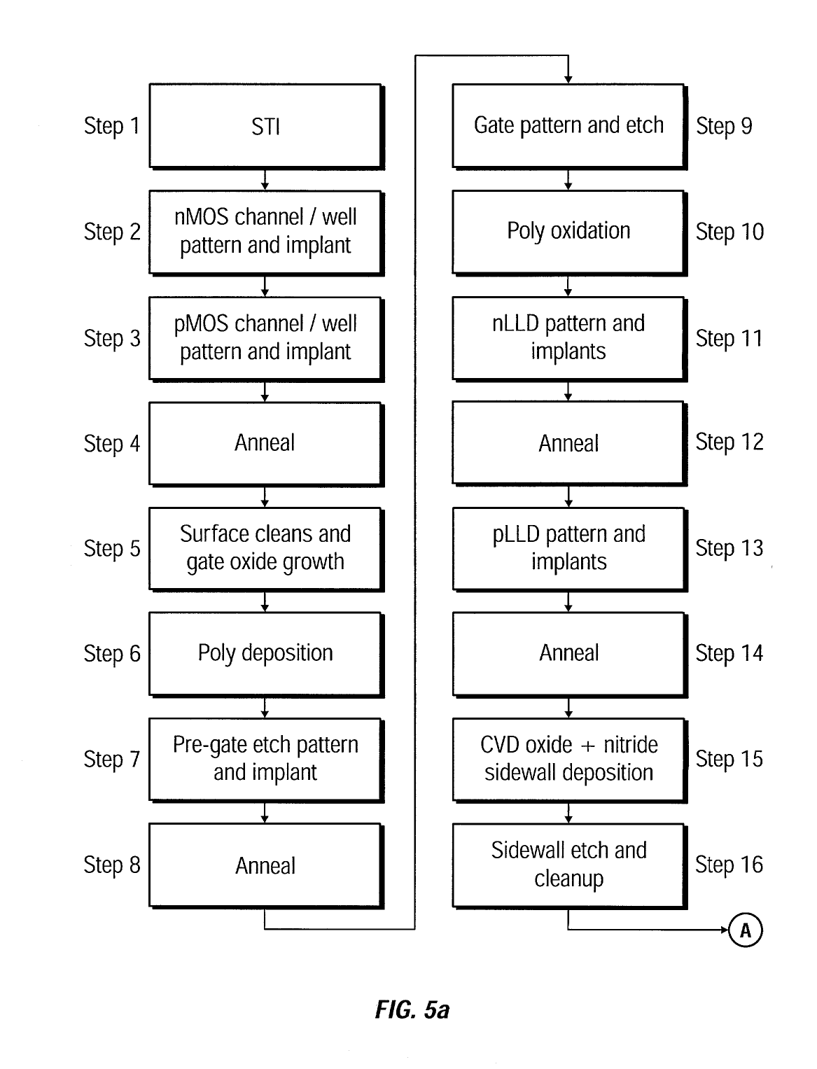

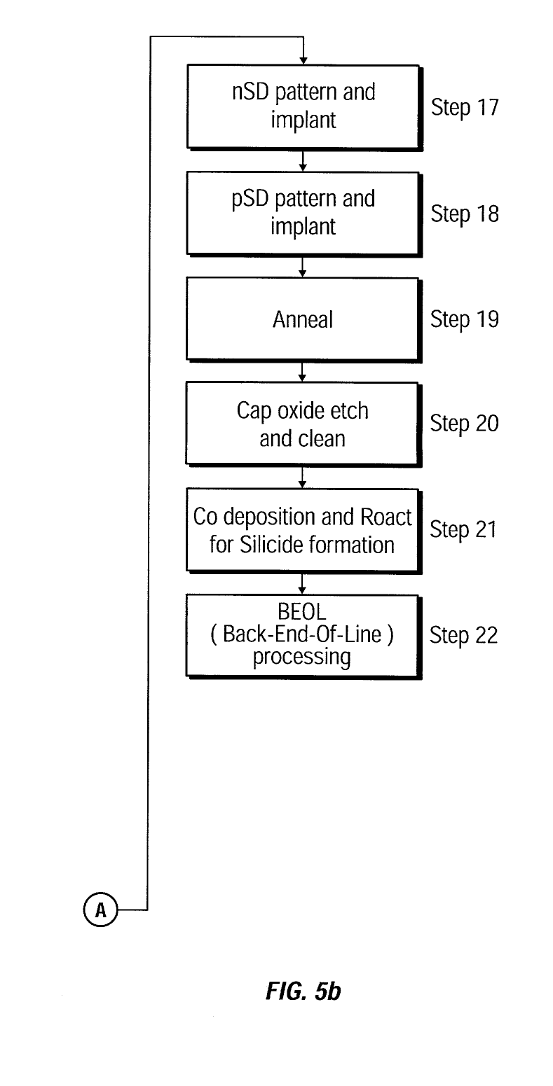

Depending on the exact implementation, the silicided area can optionally be further reduced, though possibly at added process cost. In the preferred embodiment, existing process steps are used to implement the invention, with only modifications to the layout being required. FIG. 5 shows a sample process flow for a preferred embodiment. Shallow trench isolation is used to isolate the device (step 1). This can require one or two masks, depending on the chemical mechanical polish process used. The nMOS channel/well implants are patterned and implanted (step 2) followed by the pMOS channel/well implants (step 3). This is followed by an anneal (step 4), surface cleans and gate oxide growth (step 5), and poly deposition (step 6). Pre-gate etch implants are then patterned and implanted (step 7) followed by another anneal (step 8). The gate is patterned and etched (step 9). It is in this step that the deposited poly (which was also deposited on the emitter surface during step 6) is etched, forming the necessary patterns for silicide blocking. Next comes poly oxidation (step 10), followed by nLDD (lightly doped drain) patterning and implantation (step 11), anneal (step 12), pLDD patterning and implantation (step 13) and anneal (step 14). This is followed by CVD of oxide and nitride sidewalls (step 15). It is during step 15 that the sidewalls for the poly lines that block silicide formation are created. The sidewalls are etched and cleaned up (step 16), followed by patterning and implantation of nSD (source/drain) (step 17) and pSD (step 18), and anneal (step 19). Next is the cap oxide etch and surface clean (step 20), followed by cobalt deposition and reaction for silicide formation (step 21). During this step, the location of silicide formation is determined by the pattern of the poly lines from steps 6 and 9, and the sidewalls from step 15. Next follows back end of line processing, such as forming metal contacts, etc. (step 22).

Advantages of the innovative layout include the formation of a high quality vertical BJT without added process cost, since only existing steps need layout adjustment to implement the preferred embodiment. Though the preferred embodiment is employed in a CMOS process, where no special dispensation is made for producing BJTs, the innovative layout will be beneficial in any context where BJTs are desired with minimal process alteration or budget.

According to a disclosed class of innovative embodiments, there is provided: A fabrication method, comprising the steps of: forming a bipolar transistor on an integrated circuit, said transistor having an emitter in a superficial semiconductor material; and partly siliciding said semiconductor material, while physically blocking silicide formation from part but not all of said emitter, at least partially by means of self-aligned sidewall spacers, self-aligned to a gate layer.

According to another disclosed class of innovative embodiments, there is provided: An integrated circuit structure, comprising: a bipolar transistor having an emitter; a first material formed on said emitter, said material covering a first area of said emitter; silicide formed on said emitter; wherein said silicide is not formed on said first area.

According to another disclosed class of innovative embodiments, there is provided: An integrated circuit structure, comprising: a bipolar transistor having an emitter, said emitter having a surface; polysilicon structures formed on said emitter surface; wherein said polysilicon structures block silicide formation on at least a part of said emitter surface.

Modifications and Variations

As will be recognized by those skilled in the art, the innovative concepts described in the present application can be modified and varied over a tremendous range of applications, and accordingly the scope of patented subject matter is not limited by any of the specific exemplary teachings given, but is only defined by the issued claims.

In alternative embodiments the silicide can be patterned in chevettes, S-shapes, or as islands rather than lines.

While the preferred embodiment shows no contacts between the poly lines, the spacing and configuration of the poly lines could be altered (e.g., broken at a different place than in the preferred embodiment) to make room for contacts between the poly lines. Instead of polysilicon, other materials such as metal gates or a stacked layer of metal and poly may be used.

Instead of n well and a p substrate, other embodiments can include use of another type or bipolar device. The present application contemplates use of bipolar devices of varying configurations.

Though the disclosed embodiments show that the medium doped drain (implanted before the sidewall) and deep source/drain (implanted after the sidewall) is used, the present application can also be adapted to a variety of processes where other combinations of implants are used for drain engineering. For example, only the deep source/drain may be used in the bipolar while both MDD and deep source/drain is used in MOSFETs.

While the preferred embodiment refers merely to silicide cladding, it will be recognized by those skilled in the art that a variety of contact metallizations can be used, including metals, metal/metalnitride compositions, or other layers.

Similarly, it will be readily recognized that the described process steps can also be embedded into hybrid process flows, such as smartpower processes.

The teachings above are not necessarily strictly limited to silicon. In alternative embodiments, it is contemplated that these teachings can also be applied to structures and methods using other semiconductors, such as silicon/germanium and related alloys, gallium arsenide and related compounds and alloys, indium phosphide and related compounds, and other semiconductors, including layered heterogeneous structures.

What is claimed is:

1. An integrated circuit structure, comprising:
a bipolar transistor having an emitter;
a first material formed on said emitter, said material covering a first area of said emitter;
silicide formed on said emitter;
wherein said silicide is not formed on said first area.

2. An integrated circuit structure, comprising:
a bipolar transistor having an emitter, said emitter having a surface;
polysilicon structures formed on said emitter surface;
wherein said polysilicon structures block silicide formation on at least a part of said emitter surface.

3. A fabrication method, comprising the steps of:
forming a bipolar transistor on an integrated circuit, said transistor having an emitter in a superficial semiconductor material; and
partly siliciding said semiconductor material, while physically blocking silicide formation from part but not all of said emitter, at least partially by means of self-aligned sidewall spacers.
